(19) United States
(12) Patent Application Publication
(10) Pub. No.: US 2026/0122878 A1
(43) Pub. Date: Apr. 30, 2026

(54) SEMICONDUCTOR DEVICE, MANUFACTURING METHOD THEREOF AND MEMORY SYSTEM

(71) Applicant: Yangtze Memory Technologies Co., Ltd., Wuhan (CN)

(72) Inventors: Jie PAN, Wuhan (CN); Rui SONG, Wuhan (CN); Ziyu ZHANG, Wuhan (CN); Yi ZHOU, Wuhan (CN); Yaobin FENG, Wuhan (CN)

(21) Appl. No.: 19/224,332

(22) Filed: May 30, 2025

(30) Foreign Application Priority Data
Oct. 29, 2024 (CN) 202411523985.6

(51) Int. Cl. H10B 12/00; H01L 21/285; H10D 1/68

(52) U.S. Cl. CPC H10B 12/315; H10B 12/0335; H10D 1/716; H10D 64/0112; H10B 12/05

(57) ABSTRACT

Semiconductor devices, manufacturing methods of the semiconductor devices, and memory systems are provided. In one aspect, a semiconductor device includes a first semiconductor structure that includes a semiconductor body, a capacitor structure, and a connection structure. The semiconductor body extends along a first direction. The capacitor structure is located on a side of the semiconductor body in the first direction and includes a first electrode layer. A first end of the connection structure in the first direction is in contact with the semiconductor body, and at least a part of a second end of the connection structure is located in the first electrode layer.

### CROSS-REFERENCE TO RELATED APPLICATIONS

This application claims the benefit of priority to Chinese Patent Application No. 202411523985.6, filed on Oct. 29, 2024, the disclosure of which is hereby incorporated by reference in its entirety.

### TECHNICAL FIELD

The implementation of the present disclosure relates to the field of semiconductor technology, and in particular, to a semiconductor device, a manufacturing method thereof and a memory system.

### BACKGROUND

A semiconductor device may serve as a memory device for storing information in modern information technology, the main function of which is to store programs and various data, and it can automatically access programs or data at high speed during computer operation. Taking a Dynamic Random Access Memory (DRAM) as an example, the DRAM typically comprises a plurality of memory cells. The memory cell comprises a transistor and a capacitor structure, one end of the transistor is connected to the capacitor structure, and the other end of the transistor is connected to a bit line.

### SUMMARY

The implementations of the present disclosure provide a semiconductor device, a manufacturing method thereof and a memory system.

A first aspect of the present disclosure provides a semiconductor device, comprising a first semiconductor structure, and the first semiconductor structure comprises a semiconductor body, a capacitor structure and a connection structure. The semiconductor body extends along a first direction, the capacitor structure is located on a side of the semiconductor body in the first direction and comprises a first electrode layer, one end of the connection structure in the first direction is in contact with the semiconductor body, and at least a part of the other end of the connection structure is located in the first electrode layer.

In some implementations, the connection structure protrudes from a surface of the first electrode layer facing toward the semiconductor body in the first direction and is in contact with the semiconductor body.

In some implementations, the connection structure comprises a first connection surface and a second connection surface opposite to each other in the first direction, and a surface of the first electrode layer facing toward the semiconductor body is located between the first connection surface and the second connection surface in the first direction.

In some implementations, a material of the connection structure and a material of the first electrode layer comprise the same metal element.

In some implementations, the metal element comprises molybdenum.

In some implementations, the material of the connection structure comprises a metal silicide having the metal element.

In some implementations, the connection structure is a single-layer structure.

In some implementations, a size of the connection structure in the first direction is less than 10 nm.

In some implementations, the connection structure is formed by an atomic layer deposition process.

In some implementations, a size of an end of the first electrode layer facing toward the semiconductor body in a second direction is greater than a size of the connection structure in the second direction, and the second direction intersects the first direction.

In some implementations, a size of an end of the semiconductor body in contact with the connection structure in the second direction is the same as a size of the connection structure in the second direction, and the second direction intersects the first direction.

In some implementations, the capacitor structure further comprises a second electrode layer and a capacitor dielectric layer. The second electrode layer extends along the first direction, the capacitor dielectric layer is located on a sidewall of the second electrode layer extending along the first direction and an end surface of the second electrode layer facing toward the semiconductor body, and the first electrode layer is located on a side of the capacitor dielectric layer away from the second electrode layer.

In some implementations, the capacitor structure further comprises a capacitor dielectric layer and a second electrode layer, the capacitor dielectric layer is located on at least part of a sidewall of the first electrode layer extending along the first direction, and the second electrode layer is located on a side of the capacitor dielectric layer away from the first electrode layer.

In some implementations, the capacitor structure further comprises a supporting core, and the first electrode layer is located on a sidewall of the supporting core extending along the first direction and an end surface of the supporting core facing toward the semiconductor body.

In some implementations, the first electrode layer is a pillar structure, and an end of the connection structure away from the semiconductor body in the first direction is located in the first electrode layer.

In some implementations, the first semiconductor structure further comprises a filling dielectric layer, and the first electrode layer extends through the filling dielectric layer along the first direction.

In some implementations, the first semiconductor structure further comprises a gate structure located on at least part of a sidewall of the semiconductor body extending along the first direction.

In some implementations, the first semiconductor structure further comprises an isolation structure located on a side of the semiconductor body in a second direction and extending along a third direction. The gate structure is located on a side of the semiconductor body away from the isolation structure in the second direction and extends along the third direction, and the first direction, the second direction and the third direction intersect each other.

In some implementations, the isolation structure has an air gap.

In some implementations, the first semiconductor structure further comprises a bit line located on a side of the semiconductor body away from the capacitor structure in the first direction and extending along a second direction, and the first direction intersects the second direction.

In some implementations, the semiconductor device further comprises a second semiconductor structure located on a side of the first semiconductor structure in the first direction and coupled with the first semiconductor structure, and the second semiconductor structure comprises at least one of a memory array or a peripheral circuit.

A second aspect of the present disclosure provides a manufacturing method of a semiconductor device, comprising: forming a semiconductor body extending along a first direction; and forming a capacitor structure and a connection structure, wherein the capacitor structure is located on a side of the semiconductor body in the first direction and comprises a first electrode layer, one end of the connection structure in the first direction is in contact with the semiconductor body, and at least a part of the other end of the connection structure is located in the first electrode layer.

In some implementations, the connection structure is formed in a process of forming the first electrode layer.

In some implementations, the first electrode layer and the connection structure are formed in the same fabrication process.

In some implementations, the first electrode layer and the connection structure are formed by an atomic layer deposition process.

In some implementations, forming the capacitor structure and the connection structure comprises: forming a filling dielectric layer on a side of the semiconductor body; forming a capacitor hole extending through the filling dielectric layer along the first direction; and depositing a metal material in the capacitor hole by using an atomic layer deposition process to form the first electrode layer and the connection structure in situ.

In some implementations, depositing the metal material in the capacitor hole by using the atomic layer deposition process to form the first electrode layer and the connection structure in situ comprises: depositing the metal material in the capacitor hole, so that part of the metal material reacts with part of the semiconductor body to form the connection structure, and at least part of remaining metal material forms the first electrode layer.

In some implementations, depositing the metal material in the capacitor hole to form the first electrode layer and the connection structure in situ comprises: forming the first electrode layer and the connection structure by using the atomic layer deposition process with a molybdenum-containing material as a precursor.

In some implementations, the precursor comprises molybdenum pentachloride.

In some implementations, a deposition temperature of the atomic layer deposition process is less than 1000° C.

A third aspect of the present disclosure provides a memory system, comprising a controller and the semiconductor device according to the first aspect of the present disclosure. The controller is coupled to the semiconductor device, and is configured to control the semiconductor device to store data.

It should be understood that the above description is not intended to identify critical or important features of the examples of the present disclosure, nor is it intended to limit the scope of the present disclosure. Other features of the present disclosure will become readily understood from the following description.

### BRIEF DESCRIPTION OF THE DRAWINGS

Other features, objectives and advantages of the present disclosure will become more apparent according to the detailed description of the non-limiting examples made with reference to the following drawings. The drawings are for a better understanding of this solution, and do not constitute a limitation on the present disclosure.

FIG. 1 is a schematic three-dimensional view of a memory cell according to one of the implementations of the present disclosure;

FIG. 2 is a schematic cross-sectional view of a semiconductor device according to one of the implementations of the present disclosure;

FIG. 3 is a schematic cross-sectional view of a contact structure according to one of the implementations of the present disclosure;

FIG. 4 is a flow chart of a manufacturing method of a semiconductor device according to one of the implementations of the present disclosure;

FIG. 5 to FIG. 11 are schematic diagrams of a process of a manufacturing method of a semiconductor device according to one of the implementations of the present disclosure;

FIGS. 12 to 15 are schematic cross-sectional views of a semiconductor device according to other implementations of the present disclosure;

FIG. 16 is a schematic top view of a semiconductor device according to another implementation of the present disclosure;

FIG. 17 is a flow chart of a manufacturing method of a semiconductor device according to another implementation of the present disclosure;

FIG. 18 to FIG. 30B are schematic diagrams of a process of a manufacturing method of a semiconductor device according to another implementation of the present disclosure; and

FIG. 31 is a block diagram of a system with a semiconductor device according to one implementation of the present disclosure.

### REFERENCE NUMERALS

100, first semiconductor structure; 110, second semiconductor structure; 200, semiconductor body;
200′, initial semiconductor body; 201, wafer; 202, first surface;
203, second surface; 204, first trench; 205, second trench;
205-1, first wafer trench; 205-2, second wafer trench; 210, source; 220, drain;
230, channel; 240, first dielectric layer; 250, doped layer; 300, capacitor structure; 301, capacitor hole; 310, first electrode layer; 320, second electrode layer;
330, capacitor dielectric layer; 340, supporting core; 350, filling dielectric layer;
351, second dielectric layer; 400, connection structure; 401, first connection surface;
402, second connection surface; 500, contact structure; 501, first contact hole;
502, second contact hole; 510, semiconductor layer; 520, metal silicide layer;
530, adhesive layer; 540, metal layer; 550, dielectric layer; 600, gate structure;
600′, initial gate structure; 610, gate dielectric layer; 620, gate conductive layer;
630, gate adhesive layer; 640, gate isolation layer; 650, gate cut structure;
700, isolation structure; 700′, initial isolation structure; 701, air gap;
710, isolation dielectric layer; 720, isolation conductive layer; 800, bit line;
801, first bit line trench; 810, bit line connection layer; 900, system;
901, memory system; 902, semiconductor device; 903, memory controller; 904, host.

### DETAILED DESCRIPTION

In order to have a better understanding of the present disclosure, various aspects of the present disclosure will be described in more detail with reference to the accompanying drawings. It should be understood that these detailed descriptions are merely descriptions of implementations of the present disclosure, and are not intended to limit the scope of the present disclosure in any way. Throughout the specification, like reference numbers refer to like elements. The expression “and/or” comprises any and all combinations of one or more of the associated listed items.

It should be noted that in this specification, the expressions of the first, second, third, etc. are merely used to distinguish one feature from another feature, and do not represent any limitation on the feature, and in particular, do not represent any order.

In the drawings, the thickness, size, and shape of the components have been slightly adjusted for ease of illustration. The drawings are merely examples and are not drawn to scale.

It should also be understood that expressions such as “comprise”, “comprising”, “having”, “include”, and/or “including”, and the like, are open and not closed expressions in this specification that indicate the presence of stated features, elements, and/or components, but do not preclude the presence of one or more other features, elements, components, and/or combinations thereof. Furthermore, when an expression such as “at least one of” appear after the list of listed features, it refers to the entire list of features rather than just referring to an individual element in the list. Furthermore, when describing implementations of the present disclosure, the term “may” refers to “one or more implementations of the present disclosure”. Also, the term “example” is intended to refer to an example or illustration.

Unless otherwise defined, all terms (comprising engineering terms and scientific terms) used herein have the same meaning as those of ordinary skill in the art to which this disclosure pertains. It should also be understood that unless stated explicitly in the present disclosure, words defined in commonly used dictionaries should be interpreted as having a meaning that is consistent with their meaning in the context of the related art, and should not be interpreted in an idealized or overly formal sense.

It should be noted that, in the case of no conflict, examples and features in the examples of the present disclosure may be combined with each other. In addition, unless expressly defined or contradicted with context, the specific steps included in the methods described in this disclosure are not necessarily limited to the recited order, but may be performed in any order or in parallel. The present disclosure will be described in detail with reference to the accompanying drawings in combination with the examples.

In addition, in the present disclosure, the term “layer” refers to a material portion comprising a region having a thickness. The layer may extend over the entirety of the below or above structure, or may have a range that is less than that of the below or above structure. Further, the layer may be a region of homogenous or non-homogenous continuous structure having a thickness less than that of the continuous structure. The layer may extend horizontally, vertically, and/or along sloped surfaces. The layer may comprise a plurality of sub-layers. Additionally, the term “connected” or “coupled”, when used in the present disclosure, may represent direct or indirect contact between the corresponding components, unless otherwise defined or otherwise derived from the context.

With the rapid development of semiconductor technology, the memory cell size of DRAM is getting smaller and smaller, and its array architecture has developed from 8F² to 6F², and from 6F² to 4F². The architecture of the memory varies from a planar array transistor to a recess gate array transistor, and from a recess gate array transistor to a buried saddle fin array transistor, and then from a buried saddle fin array transistor to a vertical gate transistor.

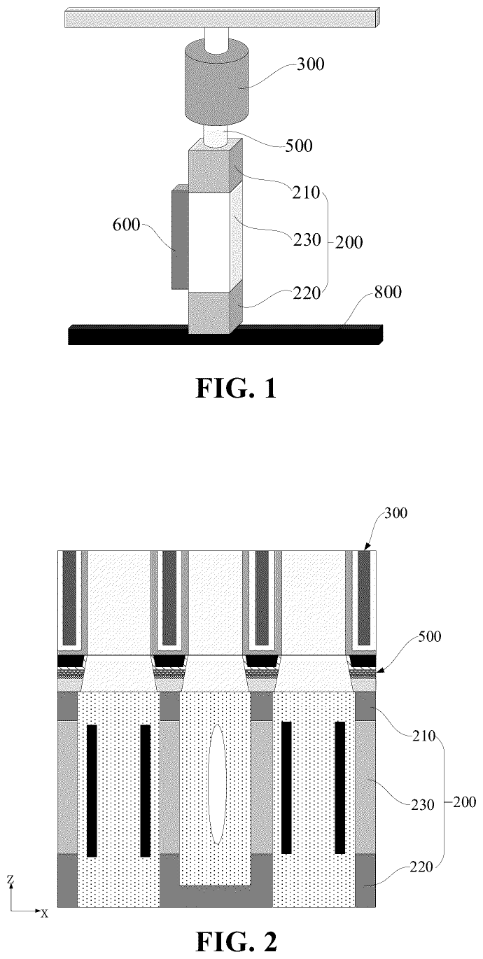

As shown in FIG. 1, the DRAM typically comprises a plurality of memory cells, each of which comprises a transistor and a capacitor structure 300, and its main operation principle is to use the amount of charges stored in the capacitor structure 300 to represent whether a binary bit is 1 or 0. The transistor typically comprises a semiconductor body 200 and a gate structure 600, a drain 220 of the semiconductor body 200 is electrically connected to a bit line (BL) 800, a source 210 of the semiconductor body 200 is electrically connected to one of the electrodes of the capacitor structure 300, another electrode of the capacitor structure 300 may be grounded or connected to a reference voltage, and a gate structure 600 of the transistor is electrically connected to a word line (WL). The word line is configured to apply a voltage to control the turn-on or turn-off of control transistor, and the bit line 800 is configured to perform a read or write operation on the capacitor structure 300 when the transistor is turned on.

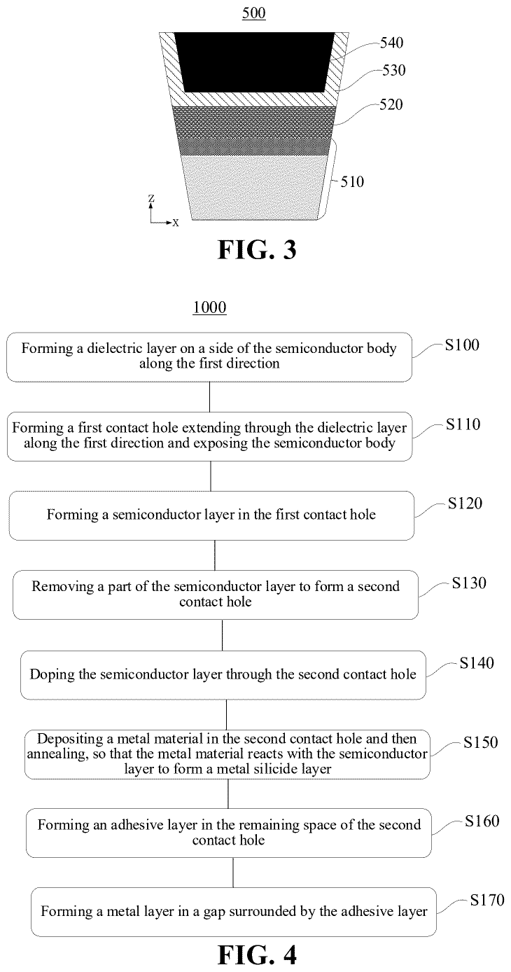

In view of the continuous decrease in the feature size of transistors, in order to reduce the contact resistance between the semiconductor body 200 and the capacitor structure 300, a contact structure 500 is provided between the semiconductor body 200 and the capacitor structure 300 in an implementation of the present disclosure. FIG. 2 illustrates a schematic cross-sectional view of an x-z plane of a semiconductor device according to one of the implementations of the present disclosure; and FIG. 3 illustrates a schematic cross-sectional view of an x-z plane of a contact structure 500 according to one of the implementations of the present disclosure. As shown in FIG. 2, the semiconductor device comprises a semiconductor body 200, a capacitor structure 300 and a contact structure 500, the contact structure 500 is located on a side of the semiconductor body 200 in the first direction, and the capacitor structure 300 is located on a side of the contact structure 500 away from the semiconductor body 200 in the first direction. In other words, the contact structure 500 is located between the semiconductor body 200 and the capacitor structure 300 in the first direction. As shown in FIG. 3, the contact structure 500 comprises a semiconductor layer 510, a metal silicide layer 520, an adhesive layer 530, and a metal layer 540. The metal silicide layer 520 is located on a side of the semiconductor layer 510 away from the semiconductor body 200, the adhesive layer 530 and the metal layer 540 are both located on a side of the metal silicide layer 520 away from the semiconductor layer 510, the adhesive layer 530 is located on a sidewall of the metal layer 540 extending along the first direction and a surface of the metal layer 540 facing toward the metal silicide layer 520 in the first direction.

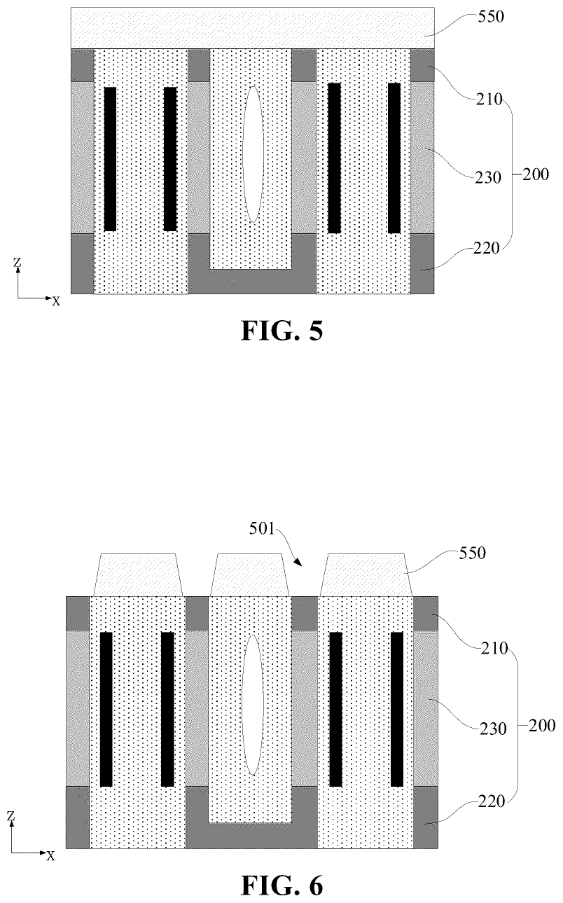

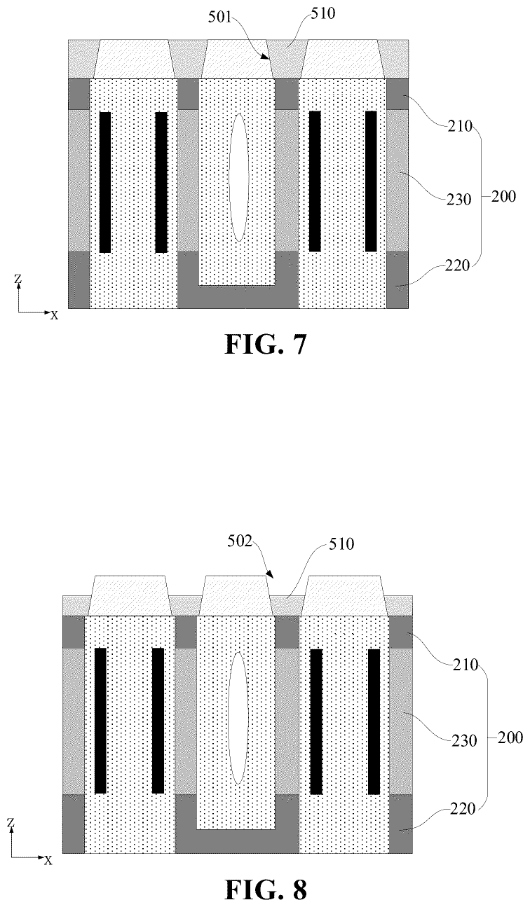

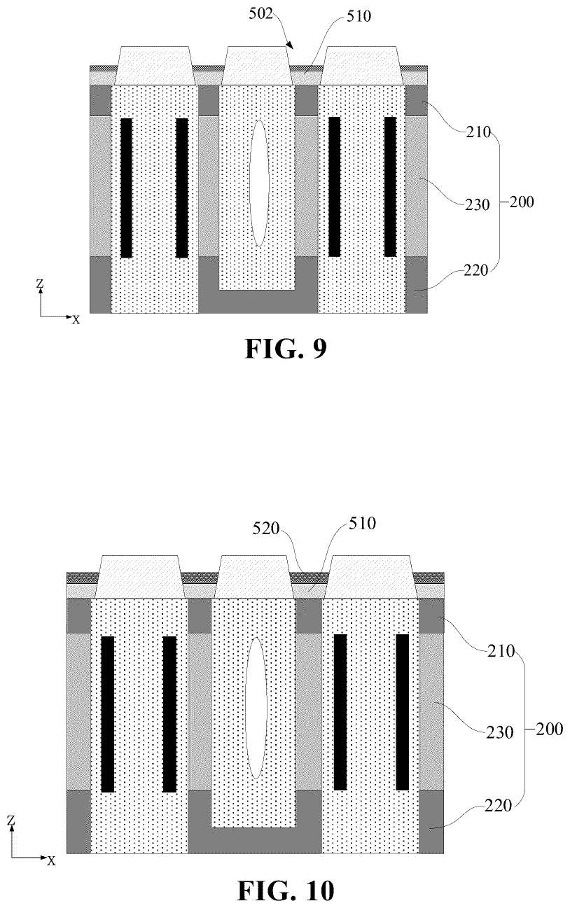

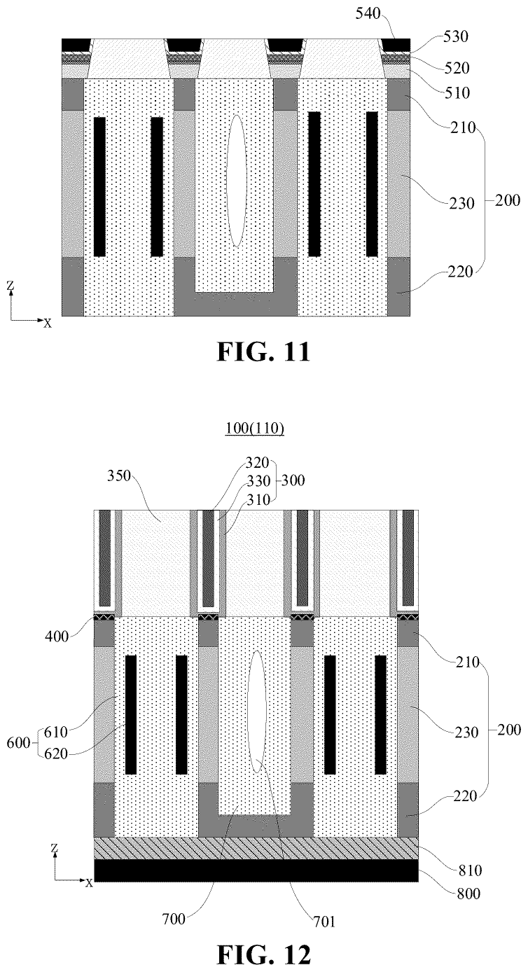

FIG. 4 illustrates a flow chart of a manufacturing method of a semiconductor device according to one of the implementations of the present disclosure, and FIG. 5 to FIG. 11 illustrate schematic diagrams of a process of a manufacturing method of a semiconductor device according to one of the implementations of the present disclosure. As shown in FIG. 4 to FIG. 11, an implementation of the present disclosure provides a manufacturing method of a semiconductor device, the manufacturing method 1000 comprises:
S100: as shown in FIG. 5, forming a dielectric layer 550 on a side of the semiconductor body 200 along the first direction, and a material of the dielectric layer 550 may comprise, but is not limited to, silicon nitride, silicon oxynitride, silicon carbonitride, or silicon boron nitride;
S110: as shown in FIG. 6, forming a first contact hole 501 extending through the dielectric layer 550 along the first direction and exposing the semiconductor body 200 from a side of the dielectric layer 550 away from the semiconductor body 200;
S120: as shown in FIG. 7, forming a semiconductor layer 510 in the first contact hole 501, and a material of the semiconductor layer 510 may comprise, but is not limited to, an elemental semiconductor material such as silicon, a compound semiconductor material such as germanium silicon, or polysilicon;
S130: as shown in FIG. 8, removing a part of the semiconductor layer 510 to form a second contact hole 502;
S140: as shown in FIG. 9, doping the semiconductor layer 510 through the second contact hole 502, wherein the dopant may comprise, but is not limited to, boron, gallium, phosphorus, arsenic or antimony;
S150: as shown in FIG. 10, depositing a metal material in the second contact hole 502 and then annealing, so that the metal material reacts with the semiconductor layer 510 to form a metal silicide layer 520, wherein a material of the metal silicide layer 520 may comprise, but is not limited to, titanium silicide or cobalt silicide;
S160: as shown in FIG. 11, forming an adhesive layer 530 on the inner wall of the remaining space of the second contact hole 502, and a material of the adhesive layer 530 may comprise, but is not limited to, at least one of titanium nitride, tantalum nitride, and tungsten carbide;
S170: forming a metal layer 540 in a gap surrounded by the adhesive layer 530, and a material of the metal layer 540 may comprise, but is not limited to, at least one of tungsten, copper and silver.

In the following, the process of forming the metal silicide layer 520 is illustrated by an example where the material of the semiconductor layer 510 is polysilicon and the material of the metal silicide layer 520 is cobalt silicide. After doping the semiconductor layer 510 through the second contact hole 502, a layer of Co thin film is deposited on the surface of the semiconductor layer 510. Next, a layer of CoN thin film is deposited on the side of the Co thin film away from the semiconductor layer 510, so as to prevent the Co from flowing during a subsequent rapid thermal annealing (RTA). Next, the rapid thermal annealing treatment is performed on the Co thin film, during which the Co reacts with the semiconductor layer 510 to generate a metal silicide with a high resistance state, the growth of the metal silicide with a high resistance state requires consumption of the semiconductor layer 510, and a growth of the metal silicide with an x thickness requires to consume the semiconductor layer 510 with a y thickness. In this process, the Co does not react with the dielectric layer 550, but only reacts with the semiconductor layer 510 to generate the metal silicide with a high resistance state, which is a body-centered orthorhombic structure having high resistance. Next, the CoN thin film and the unreacted Co thin film is removed by using a selective wet etching process, and the metal silicide with a high resistance state undergoes the rapid thermal annealing treatment, which converts the metal silicide with a high resistance state into the CoSi with a low resistance state. The CoSi with a low resistance state is a surface-centered orthorhombic structure having low resistance, and it forms the metal silicide layer 520.

In order to reduce the contact resistance between the semiconductor body 200 and the capacitor structure 300, the implementation of the present disclosure provides another semiconductor device. FIGS. 12 to 15 illustrate schematic cross-sectional views of an x-z plane of a semiconductor device according to different implementations of the present disclosure; and FIG. 16 illustrates a schematic top view of an x-y plane of a semiconductor device according to one implementation of the present disclosure.

As shown in FIG. 12 to FIG. 16, the semiconductor device comprises a first semiconductor structure 100. The first semiconductor structure 100 comprises a semiconductor body 200, a capacitor structure 300 and a connection structure 400, the semiconductor body 200 extends along a first direction, the capacitor structure 300 is located on a side of the semiconductor body 200 in the first direction, the capacitor structure 300 comprises a first electrode layer 310, one end of the connection structure 400 in the first direction is in contact with the semiconductor body 200, and at least a part of the other end of the connection structure 400 is located in the first electrode layer 310.

It should be noted that, in the implementations of the present disclosure, the first electrode layer 310 may be, but is not limited to, a pillar structure or a cylinder structure. When the first electrode layer 310 is a cylinder structure, one end of the connection structure 400 is in contact with the semiconductor body 200, and the other end of the connection structure 400 is located in the first electrode layer 310 or extends through the bottom of the first electrode layer 310 along the first direction. When the first electrode layer 310 is a pillar structure, one end of the connection structure 400 is in contact with the semiconductor body 200, and the other end of the connection structure 400 is located in the first electrode layer 310. As an example, a size of the connection structure 400 in the first direction may be, but is not limited to, less than 10 nm. In some implementations, the connection structure 400 may be a single-layer structure.

In addition, the semiconductor device provided in the implementation of the present disclosure may be a memory or part of a memory. For example, in a case where the semiconductor device comprises only the first semiconductor structure 100 and the memory comprises a peripheral circuit and the above semiconductor device, the semiconductor device is part of the memory. As an example, the first direction in the implementation of the present disclosure may be the z direction in the figures.

In some implementations, the connection structure 400 protrudes from the surface of the first electrode layer 310 facing toward the semiconductor body 200 in the first direction and is in contact with the semiconductor body 200. As shown in FIG. 27B, the connection structure 400 comprises a first connection surface 401 and a second connection surface 402 opposite to each other in the first direction, and the surface of the first electrode layer 310 facing toward the semiconductor body 200 is located between the first connection surface 401 and the second connection surface 402 in the first direction. As an example, a part of the connection structure 400 is located in the first electrode layer 310, and another part of the connection structure 400 is located on a side of the first electrode layer 310 facing toward the semiconductor body 200 and connected to the semiconductor body 200.

In some implementations, the connection structure 400 and the first electrode layer 310 may be formed in the same fabrication process. As an example, the connection structure 400 and the first electrode layer 310 may be formed by an atomic layer deposition (ALD) process.

In some implementations, a material of the connection structure 400 and a material of the first electrode layer 310 may comprise the same metal element. For example, the material of the connection structure 400 and the material of the first electrode layer 310 each comprise a molybdenum element.

In some implementations, a material of the first electrode layer 310 comprises a metal element, and a material of the connection structure 400 comprises a metal silicide having the above metal element. For example, the material of the first electrode layer 310 comprises molybdenum, and the material of the connection structure 400 comprises molybdenum silicide. It should be noted that, in addition to molybdenum, other metal materials suitable for the atomic layer deposition process and capable of reacting with the semiconductor body 200 at a high temperature such as less than 1000° C. to form the metal silicide may also be used as the material of the first electrode layer 310, which is not limited in the present disclosure.

In some implementations, a size of an end of the first electrode layer 310 facing toward the semiconductor body 200 in the second direction is greater than a size of the connection structure 400 in the second direction, and the second direction intersects the first direction.

Those skilled in the art should understand that if the first electrode layer 310 has a cylinder shape, the size of the first electrode layer 310 in the second direction generally refers to the outer diameter of the first electrode layer 310. The first direction intersecting the second direction may generally be understood as that the first direction has an included angle with the second direction. For example, the first direction and the second direction are perpendicular or substantially perpendicular to each other. As an example, the first direction in the implementation of the present disclosure may be the z direction in the figures, and the second direction may be the x direction in the figures.

For example, the first electrode layer 310 comprises a first electrode terminal and a second electrode terminal (not shown) opposite to each other in the first direction, the first electrode terminal is closer to the semiconductor body 200 than the second electrode terminal, at least a part of the connection structure 400 is located in the first electrode terminal, and a size of the first electrode terminal in the second direction is greater than a size of the connection structure 400 in the second direction.

In some implementations, a size of an end of the semiconductor body 200 in contact with the connection structure 400 in the second direction is the same as a size of the connection structure 400 in the second direction, and the second direction intersects the first direction. For example, the semiconductor body 200 comprises a first end and a second end opposite to each other in the first direction, the first end is closer to the first electrode layer 310 than the second end, the first end of the semiconductor body 200 is in contact with the connection structure 400, and the size of the first end in the second direction is the same as the size of the connection structure 400 in the second direction. It should be understood by those skilled in the art that, the size of the first end in the second direction being the same as the size of the connection structure 400 in the second direction generally refers to that the size of the first end in the second direction is exactly equal to the size of the connection structure 400 in the second direction or there is a slight deviation, for example, the difference between the two sizes does not exceed 15% of any one of the two sizes.

In some implementations, as shown in FIG. 12, the capacitor structure 300 may comprise a first electrode layer 310, a second electrode layer 320, and a capacitor dielectric layer 330. The second electrode layer 320 extends along the first direction, the capacitor dielectric layer 330 is located on a sidewall of the second electrode layer 320 extending along the first direction and an end surface of the second electrode layer 320 facing toward the semiconductor body 200, and the first electrode layer 310 is located on a side of the capacitor dielectric layer 330 away from the second electrode layer 320. As an example, the first electrode layer 310 is a cylinder structure, the second electrode layer 320 is located on the inner side of the first electrode layer 310, and the capacitor dielectric layer 330 is located between the first electrode layer 310 and the second electrode layer 320.

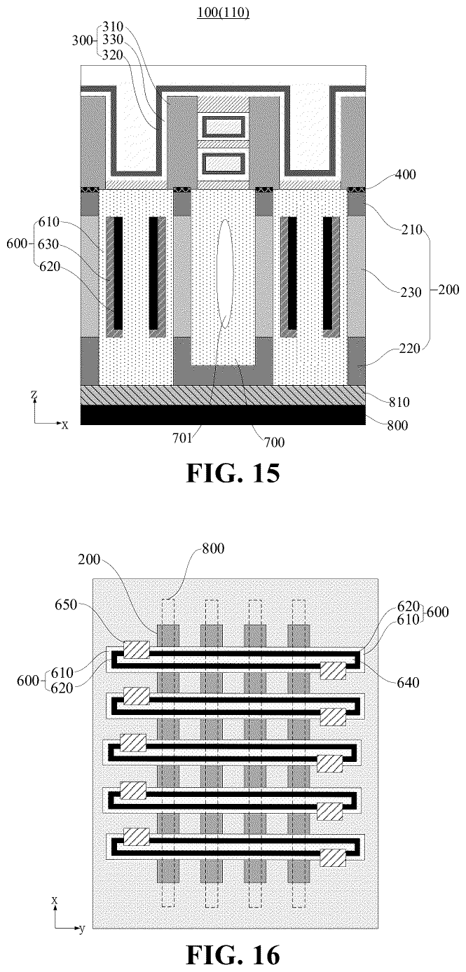

In the above implementations, the first electrode layer 310 may be located on the outer side of the second electrode layer 320; and in some other implementations, the first electrode layer 310 may also be located on the inner side of the second electrode layer 320. For example, as shown in FIG. 14 and FIG. 15, the capacitor structure 300 comprises a first electrode layer 310, a second electrode layer 320 and a capacitor dielectric layer 330. The first electrode layer 310 extends along the first direction, the capacitor dielectric layer 330 is located on part of the sidewall of the first electrode layer 310 extending along the first direction, and the second electrode layer 320 is located on a side of the capacitor dielectric layer 330 away from the first electrode layer 310. For example, as shown in FIG. 14, the first electrode layer 310 is a cylinder structure, the capacitor dielectric layer 330 is located on part of an outer wall of the first electrode layer 310, and the second electrode layer 320 is located on a side of the capacitor dielectric layer 330 away from the first electrode layer 310. In this case, the capacitor structure 300 may further comprise a supporting core 340 extending along the first direction, and the first electrode layer 310 is located on a sidewall of the supporting core 340 extending along the first direction and an end surface of the supporting core 340 facing toward the semiconductor body 200. The material of the supporting core 340 may comprise, but is not limited to, an elemental semiconductor material such as silicon (Si), a compound semiconductor material such as germanium silicon (GeSi), or polysilicon doped with a dopant such as boron. As another example, as shown in FIG. 15, the first electrode layer 310 is a pillar structure, the capacitor dielectric layer 330 is located on part of a sidewall of the first electrode layer 310, and the second electrode layer 320 is located on a side of the capacitor dielectric layer 330 away from the first electrode layer 310. It should be noted that, in addition to the above structure, the capacitor structure 300 in the implementation of the present disclosure may adopt other structures suitable for the present disclosure.

In some implementations, the first semiconductor structure 100 may further comprise a filling dielectric layer 350, and the first electrode layer 310 extends through the filling dielectric layer 350 along the first direction. The filling dielectric layer 350 may be a single-layer structure or a multi-layer structure. For example, as shown in FIG. 14 and FIG. 15, the filling dielectric layer 350 may comprise a plurality of second dielectric layers 351 spaced apart in the first direction.

In addition, the material of the first electrode layer 310 and the material of the second electrode layer 320 may be the same or different. The materials of the first electrode layer 310 and the second electrode layer 320 may comprise, but are not limited to, at least one of a metal, a metal compound, a semiconductor material, and a silicide; for example, the materials of the first electrode layer 310 and the second electrode layer 320 may comprise titanium nitride, titanium silicide, or nickel silicide. The material of the capacitor dielectric layer 330 may comprise, but is not limited to, at least one of aluminum oxide, tantalum oxide, titanium oxide, yttrium oxide, zirconium oxide, zirconium silicon oxide, hafnium oxide, hafnium silicon oxide, hafnium silicon oxynitride, hafnium zirconate, lanthanum oxide, lanthanum aluminum oxide, lanthanum hafnium oxide, hafnium aluminum oxide, and prascodymium oxide.

In some implementations, the first semiconductor structure 100 may further comprise a gate structure 600 located on at least part of a sidewall of the semiconductor body 200 extending along the first direction. As an example, the gate structure 600 may comprise a gate dielectric layer 610 and a gate conductive layer 620. The gate dielectric layer 610 is located on a sidewall of the semiconductor body 200, and the gate conductive layer 620 is located on a side of the gate dielectric layer 610 away from the semiconductor body 200. A material of the gate dielectric layer 610 may comprise, but is not limited to, silicon oxide, silicon oxynitride, silicon nitride, or a high-K material such as hafnium oxide, zirconium oxide, aluminum oxide, tantalum oxide, or the like; and a material of the gate conductive layer 620 may comprise tungsten, aluminum, titanium, copper, cobalt, or tungsten nitride. In order to improve the adhesion between the gate conductive layer 620 and the gate dielectric layer 610, the gate structure 600 may further comprise a gate adhesive layer 630 located between the gate dielectric layer 610 and the gate conductive layer 620. The material of the gate adhesive layer 630 may comprise, but is not limited to, at least one of titanium nitride, tantalum nitride, and tungsten carbide.

It should be noted that the gate structure 600 may cover part of the sidewall of the semiconductor body 200, or may cover the entire sidewall of the semiconductor body 200. Thus, the transistor may be classified into a single-gate transistor, double-gate transistor, triple-gate transistor, or gate-all-around (GAA) transistor. In the single-gate transistor, in a direction intersecting the first direction, the gate structure 600 may be located only on one side of the semiconductor body 200; in the double-gate transistor, in a direction intersecting the first direction, the gate structure 600 may be located on two opposite sides of the semiconductor body 200; in the triple-gate transistor, in a direction intersecting the first direction, the gate structure 600 partially surrounds the semiconductor body 200; and in the gate-all-around transistor, in a direction intersecting the first direction, the gate structure 600 surrounds the semiconductor body 200. For example, the semiconductor body 200 comprises a first sidewall and a second sidewall opposite to each other in the second direction, and a third sidewall and a fourth sidewall opposite to each other in the third direction, and the first direction, the second direction and the third direction intersect each other. If the gate structure 600 is located on any one of the first sidewall, the second sidewall, the third sidewall and the fourth sidewall of the semiconductor body 200, the transistor formed by the gate structure 600 and the semiconductor body 200 is a single-gate transistor; if the gate structure 600 is located on the first sidewall and the second sidewall (or the third sidewall and the fourth sidewall) of the semiconductor body 200, the transistor formed by the gate structure 600 and the semiconductor body 200 is a double-gate transistor; if the gate structure 600 is located on any three of the first sidewall, the second sidewall, the third sidewall and the fourth sidewall of the semiconductor body 200, the transistor formed by the gate structure 600 and the semiconductor body 200 is a triple-gate transistor; and if the gate structure 600 is located on the first sidewall, the second sidewall, the third sidewall and the fourth sidewall of the semiconductor body 200, the transistor formed by the gate structure 600 and the semiconductor body 200 is a gate-all-around transistor.

The first direction, the second direction and the third direction intersecting each other may be generally understood as that the first direction, the second direction and the third direction have an included angle between each other. As an example, the first direction in the implementation of the present disclosure may be the z direction in the figures, the second direction may be the x direction in the figures, and the third direction may be the y direction in the figures.

Taking the single-gate transistor as an example, the first semiconductor structure 100 may further comprise an isolation structure 700. The isolation structure 700 is located on a side of the semiconductor body 200 in the second direction and extends along the third direction, the gate structure 600 is located on a side of the semiconductor body 200 away from the isolation structure 700 in the second direction and extends along the third direction, and the first direction, the second direction and the third direction intersect each other.

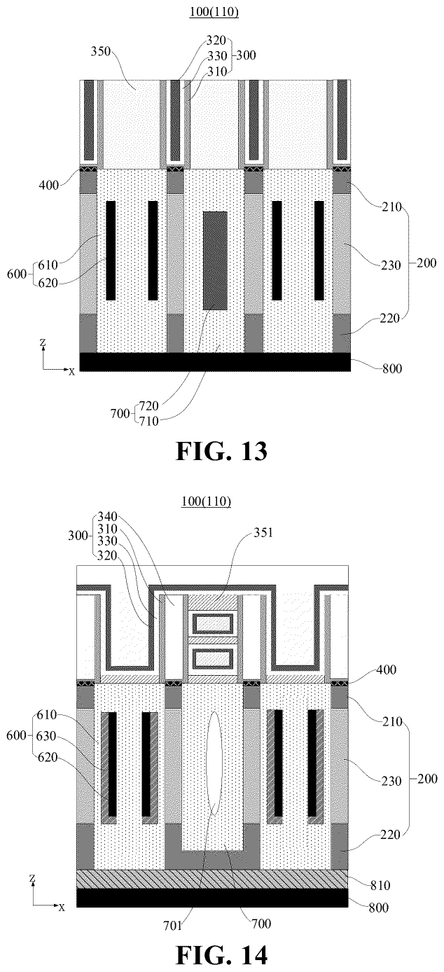

As an example, as shown in FIG. 12, the isolation structure 700 has an air gap 701. In some other implementations, as shown in FIG. 13, the isolation structure 700 may comprise an isolation dielectric layer 710 and an isolation conductive layer 720, and the isolation dielectric layer 710 is at least located on a sidewall of the isolation conductive layer 720 extending along the first direction. A material of the isolation dielectric layer 710 may comprise, but is not limited to, silicon oxide, silicon oxynitride, or silicon nitride; and a material of the isolation conductive layer 720 may comprise, but is not limited to, at least one of tungsten, titanium nitride, copper, and silver.

In some implementations, the first semiconductor structure 100 may further comprise a bit line 800 located on a side of the semiconductor body 200 away from the capacitor structure 300 in the first direction. The bit line 800 may extend along the second direction, and a plurality of semiconductor bodies 200 spaced apart in the second direction are connected to the bit line 800. The material of the bit line 800 may comprise, but is not limited to, a metal material such as tungsten, copper or aluminum. As an example, the first semiconductor structure 100 may further include a bit line connection layer 810 located on a side of the bit line 800 facing toward the semiconductor body 200. In other words, the bit line connection layer 810 is located between the bit line 800 and the semiconductor body 200 in the first direction, and the bit line connection layer 810 extends along the second direction. The material of the bit line connection layer 810 may comprise, but is not limited to, a semiconductor material having a P-type dopant such as boron or gallium or an N-type dopant such as phosphorus or arsenic.

As an example, the semiconductor body 200 may comprise a source 210, a drain 220, and a channel 230 between the source 210 and the drain 220 in the first direction. The semiconductor body 200 and the gate structure 600 constitute a transistor, the source 210 is in contact with the connection structure 400, the drain 220 is connected to the bit line 800, the gate structure 600 may serve as a word line configured to apply a voltage to control the turn-on or turn-off of the transistor, the bit line 800 is configured to perform a read or write operation on the capacitor structure 300 when the transistor is turned on, and the amount of charges stored in the capacitor structure 300 represents whether one binary bit is 1 or 0.

In some implementations, the semiconductor device may further comprise a second semiconductor structure 110 located on a side of the first semiconductor structure 100 in the first direction and coupled to the first semiconductor structure 100. The second semiconductor structure 110 may comprise, but is not limited to, at least one of a memory array or a peripheral circuit. For example, the first semiconductor structure 100 and the second semiconductor structure 110 may be coupled by bonding.

The memory array may comprise, but is not limited to, a DRAM memory array. The peripheral circuit may comprise a peripheral device, which may comprise, but is not limited to, at least one of a high-voltage device, a low-voltage device, and an ultra-low-voltage device, and the high-voltage device, the low-voltage device, or the ultra-low-voltage device may comprise at least one of an active or passive device such as a transistor, a diode, a resistor, and a capacitor. The high-voltage device may comprise, but is not limited to, at least one of a row decoder, a column decoder, a word line driver, and a bit line driver. The low-voltage device may comprise, but is not limited to, a page buffer or a logic device. The ultra-low-voltage device may comprise, but is not limited to, an I/O circuit. The working voltage of the high-voltage device is generally greater than 3.3V, for example, 5V-30V, as an example, the working voltage of the high-voltage device may be 5V, 10V, 15V, 20V, 25V or 30V; the working voltage of the low-voltage device is generally between 1.3V and 3.3V, as an example, the working voltage of the low-voltage device may be 1.3V, 1.8V, 2.3V, 2.8V, or 3.3V; the working voltage of the ultra-low-voltage device is generally lower than 1.3V, for example, 0.9V to 1.2V; as an example, the working voltage of the ultra-low-voltage device may be 0.9V, 0.95V, 1V, 1.05V, 1.1V, 1.15V, or 1.2V. It should be noted that the working voltage of the high-voltage device, the low-voltage device, or the ultra-low-voltage device may also be any value between any two of the above voltage values. It should be understood by those skilled in the art that the above description of the ranges of the working voltages of the high-voltage device, the low-voltage device, and the ultra-low-voltage device is for a better understanding of the present disclosure, and does not constitute a limitation on the present disclosure.

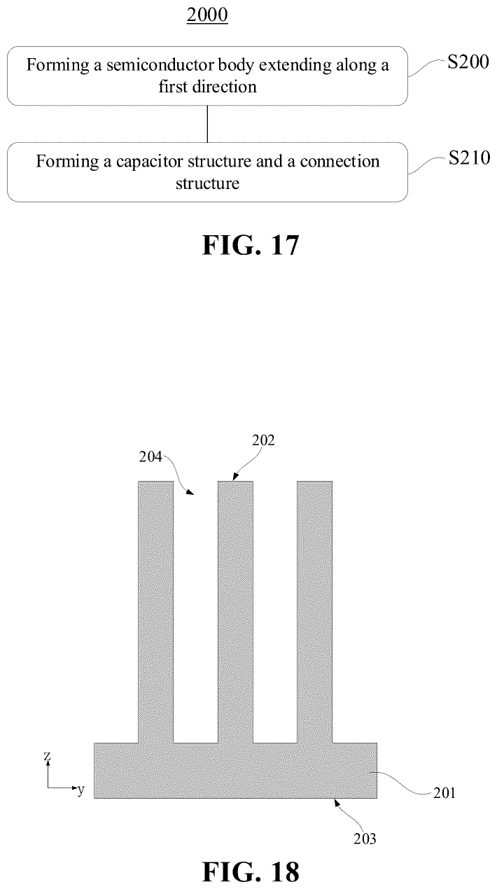

FIG. 17 illustrates a flow chart of a manufacturing method of a semiconductor device according to one implementation of the present disclosure, and FIG. 18 to FIG. 30B illustrate schematic diagrams of a process of a manufacturing method of a semiconductor device according to one implementation of the present disclosure. As shown in FIG. 17 to FIG. 30B, the manufacturing method 2000 comprises:
S200: forming a semiconductor body 200 extending along a first direction;
S210: forming a capacitor structure 300 and a connection structure 400, wherein the capacitor structure 300 is located on a side of the semiconductor body 200 in the first direction and comprises a first electrode layer 310, one end of the connection structure 400 in the first direction is in contact with the semiconductor body 200, and at least a part of the other end of the connection structure 400 is located in the first electrode layer 310.

The operations in the manufacturing method of the semiconductor device in the implementations of the present disclosure are described in details below.

### S200

In S200, a semiconductor body 200 extending along a first direction is formed. A projection shape of the semiconductor body 200 in a plane perpendicular to the first direction may be, but is not limited to, a rectangle, a circle, an ellipse, a semicircle, or any other shape, which is not limited in the present disclosure.

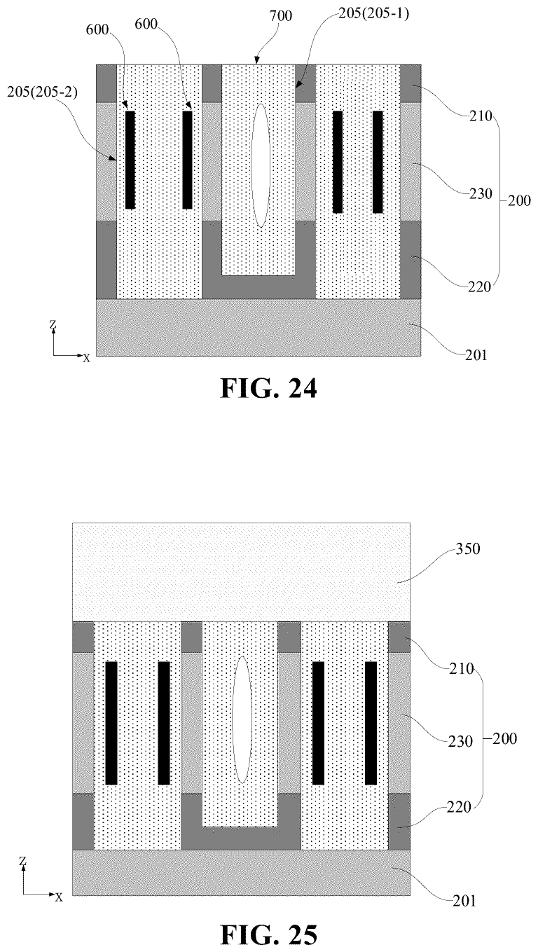

FIG. 18 illustrates a schematic cross-sectional view of a y-z plane of forming a first trench 204 in a wafer 201 according to an implementation of the present disclosure; FIG. 23 illustrates a schematic cross-sectional view of an x-z plane of forming an initial gate structure 600′ in a second wafer trench 205-2 according to an implementation of the present disclosure; and FIG. 24 illustrates a schematic cross-sectional view of an x-z plane of forming a source 210 according to an implementation of the present disclosure.

As an example, the semiconductor body 200 may be formed by following operations. A plurality of first trenches 204 spaced apart in a third direction and each extending along a second direction are formed in the wafer 201 as shown in FIG. 18, wherein the material of the wafer 201 may be any suitable semiconductor material, for example, may be an elemental semiconductor material such as silicon (Si) or germanium (Ge), or may be a compound semiconductor material such as silicon-on-insulator (SOI) or germanium-on-insulator (GeOI). As shown in FIG. 23, a plurality of second trenches 205 spaced apart in a second direction and each extending along a third direction are formed in the wafer 201 to divide the wafer 201 into a plurality of initial semiconductor bodies 200′. As shown in FIG. 24, the semiconductor body 200 is formed based on the initial semiconductor body 200′, for example, the semiconductor body 200 is formed by doping two ends of the initial semiconductor body 200′ in the first direction. The first trench 204 and the second trench 205 may be formed in the wafer 201 by a wet etching process, a dry etching process such as a plasma etching process or a reactive ion etching process, or any combination thereof. As an example, a size of the first trench 204 in the first direction and a size of the second trench 205 in the first direction may be smaller than a size of the wafer 201 in the first direction.

It should be noted that the above operations may be performed in parallel, in sequence, or in different orders, as long as the semiconductor body 200 can be formed, which is not limited in the present disclosure. For example, the plurality of second trenches 205 comprise a first wafer trench 205-1 and a second wafer trench 205-2 that are arranged alternately in the second direction, for example, the first wafer trench 205-1 and the second wafer trench 205-2 may be formed in different fabrication processes.

In some implementations, the manufacturing method may further comprise: forming the gate structure 600 on at least part of a sidewall of the initial semiconductor body 200′ extending along the first direction. After the gate structure 600 is formed, the semiconductor body 200 may be formed based on the initial semiconductor body 200′, and the semiconductor body 200 and the gate structure 600 together constitute a transistor. As described above, the gate structure 600 may cover part of the sidewall of the semiconductor body 200, or may cover the entire sidewall of the semiconductor body 200. Thus, the transistor may be classified into a single-gate transistor, a double-gate transistor, a triple-gate transistor, or a gate-all-around (GAA) transistor.

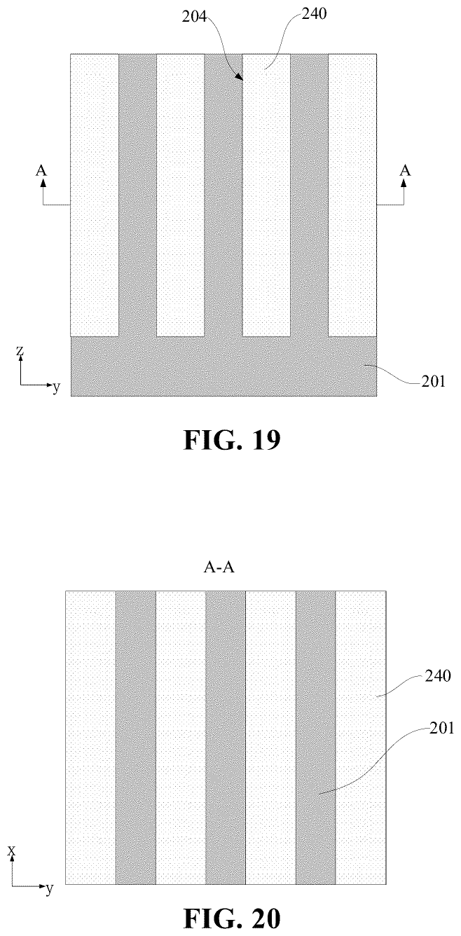

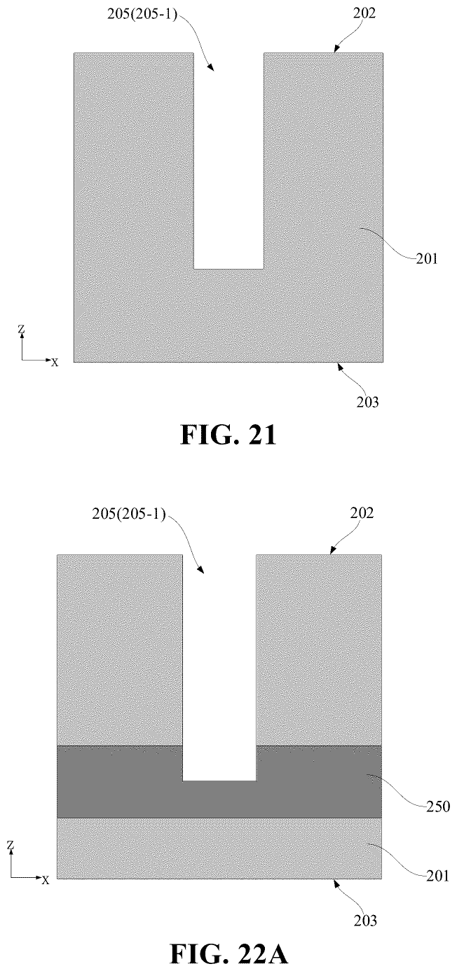

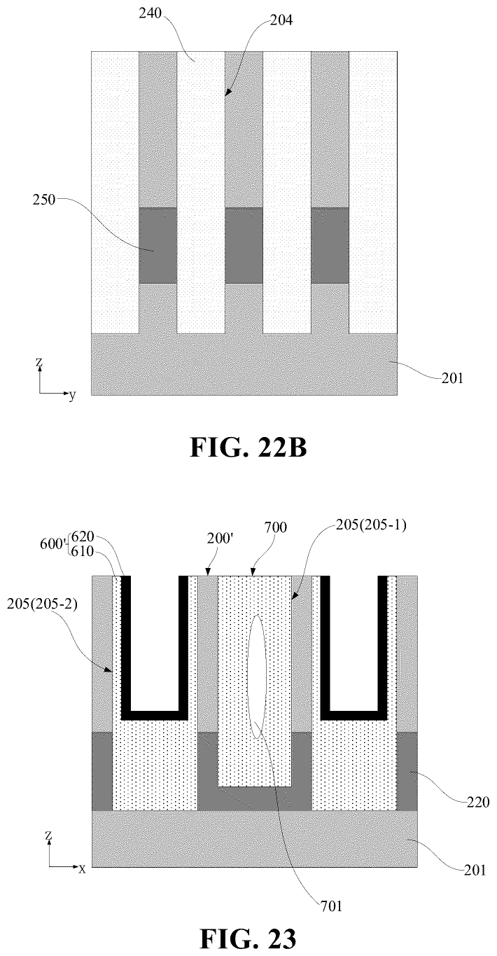

FIG. 19 illustrates a schematic cross-sectional view of a y-z plane of forming a first dielectric layer 240 in a first trench 204 according to an implementation of the present disclosure; FIG. 20 illustrates a schematic cross-sectional view of FIG. 19 at A-A; FIG. 21 illustrates a schematic cross-sectional view of an x-plane of forming a first wafer trench 205-1 in a wafer 201 according to an implementation of the present disclosure; FIG. 22A illustrates a schematic cross-sectional view of an x-z plane of doping the bottom of the first wafer trench 205-1 to form a doped layer 250 according to an implementation of the present disclosure; and FIG. 22B illustrates a schematic cross-sectional view of a y-z plane of doping the bottom of the first wafer trench 205-1 to form a doped layer 250 according to an implementation of the present disclosure.

An example of a method for forming a single-gate transistor is illustrated as following. A wafer 201 is provided, which comprises a first surface 202 and a second surface 203 opposite to each other in a first direction. As shown in FIG. 18, a plurality of first trench 204 spaced apart in a third direction and each extending along a second direction in the wafer 201 is formed from the first surface 202 of wafer 201; as an example, the size of the first trench 204 in the first direction is smaller than the size of the wafer 201 in the first direction, in other words, the first trench 204 does not extend through the wafer 201. As shown in FIG. 19 and FIG. 20, a dielectric material is deposited in the first trench 204 to form a first dielectric layer 240, wherein a material of the first dielectric layer 240 may comprise, but is not limited to, silicon nitride, silicon oxynitride, silicon carbide, or silicon oxide. As shown in FIG. 21, a plurality of first wafer trench 205-1 spaced apart in the second direction and each extending in the third direction in the wafer 201 is formed from the first surface 202 of the wafer 201. As shown in FIG. 22A and FIG. 22B, the bottom of the first wafer trench 205-1 is doped to form a doped layer 250 located between the first surface 202 and the second surface 203 in the first direction. As shown in FIG. 23, an isolation structure 700 in the first wafer trench 205-1 is formed. A second wafer trench 205-2 extending along the third direction between adjacent first wafer trenches 205-1 is formed from the first surface 202 of the wafer 201, and the second wafer trench 205-2 extends through the doped layer 250 along the first direction. As an example, a size of the second wafer trench 205-2 in the first direction is greater than a size of the first wafer trench 205-1 in the first direction, and smaller than a size of the first trench 204 in the first direction. Thus, the first trench 204, the first wafer trench 205-1 and the second wafer trench 205-2 together divide a portion of the wafer 201 in the first direction into a plurality of initial semiconductor bodies 200′, and the doped layer 250 is divided into a plurality of drains 220 by the plurality of second wafer trenches 205-2. An initial gate structure 600′ is formed in the second wafer trench 205-2. As shown in FIG. 24, the initial gate structure 600′ is divided into two gate structures 600 opposite to each other in the second direction; and the end of the initial semiconductor body 200′ is doped from the first surface 202 to form the source 210. Thus, the initial semiconductor body 200′ is doped twice as above to form the semiconductor body 200, and the semiconductor body 200 comprises a source 210, a drain 220, and a channel 230 between the source 210 and the drain 220. The source 210 and the drain 220 may both be doped with a P-type dopant, or may both be doped with an N-type dopant, and the dopants of the source 210 and the drain 220 may be the same or different. For example, the dopants may comprise, but are not limited to, boron (B), aluminum (Al), gallium (Ga), phosphorus (P), arsenic (As), or antimony (Sb).

As an example, the initial gate structure 600′ may comprise a gate dielectric layer 610 and a gate conductive layer 620. The initial gate structure 600′ may be formed by following operations. A gate dielectric layer 610 is formed on an inner wall of the second wafer trench 205-2, wherein the gate dielectric layer 610 may be formed by in situ oxidization of an inner wall of the second wafer trench 205-2, or may be formed by a thin film deposition process, and a material of the gate dielectric layer 610 may comprise, but is not limited to, silicon oxide, silicon oxynitride, silicon nitride, or a high-K material such as hafnium oxide, zirconium oxide, aluminum oxide, tantalum oxide, or the like. A gate conductive layer 620 is formed on a side of the gate dielectric layer 610 away from the inner wall of the second wafer trench 205-2, and a material of the gate conductive layer 620 may comprise, but is not limited to, polysilicon, metal, metal compound, silicide, or any combination thereof. For example, the material of the gate conductive layer 620 may comprise tungsten, aluminum, titanium, copper, cobalt, or tungsten nitride. In addition, in order to improve adhesion between the gate conductive layer 620 and the gate dielectric layer 610, the initial gate structure 600′ may further comprise a gate adhesive layer 630. Thus, before forming the gate conductive layer 620, the gate adhesive layer 630 may also be formed on a side of the gate dielectric layer 610 away from the inner wall of the second wafer trench 205-2, and the material of the gate adhesive layer 630 may comprise, but is not limited to, at least one of titanium nitride, tantalum nitride, and tungsten carbide.

The gate dielectric layer 610, the gate conductive layer 620 and the gate adhesive layer 630 may each be formed by a thin film deposition process, which may be, but is not limited to, a physical vapor deposition (PVD) process, a chemical vapor deposition (CVD) process, an atomic layer deposition (ALD) process, or any combination thereof.

After the initial gate structure 600′ is formed, the initial gate structure 600′ may be divided into two gate structures 600 by following operations. At least a part of the initial gate structure 600′ at the bottom of the second wafer trench 205-2 is removed through the gap surrounded by the initial gate structure 600′ by using a punching process, so that the remaining initial gate structure 600′ covers the sidewall of the second wafer trench 205-2 extending along the first direction and has a ring shape. As shown in FIG. 16, the gate isolation layer 640 is formed in the gap surrounded by the initial gate structure 600′, and the material of the gate isolation layer 640 may be, but is not limited to, silicon oxide, silicon oxynitride, silicon nitride, or a high-K material such as hafnium oxide, zirconium oxide, aluminum oxide, tantalum oxide, etc. Part of the initial gate structure 600′ is removed from the first surface 202 of the wafer 201 to form a gate trench (not shown). The isolation material is filled in the gate structure 600, and the isolation material, the material of the gate dielectric layer 610 and the material of the gate isolation layer 640 may be the same or different. If these three materials are the same, there may not be an obvious detectable interface between the isolation material filled in the gate trench and the gate dielectric layer 610 and between the isolation material and the gate isolation layer 640. A gate cut structure 650 is formed at each end of the remaining initial gate structure 600′ along the third direction, and the gate cut structure 650 extends through the initial gate structure 600′ along the first direction to divide the remaining initial gate structure 600′ into two gate structures 600 opposite to each other in the second direction.

As an example, the isolation structure 700 may be formed by following operations. A dielectric material is deposited in the first wafer trench 205-1 to form the isolation structure 700. As an example, the isolation structure 700 may have an air gap 701, and the isolation material may be deposited at two different deposition rates in the first wafer trench 205-1 when forming the isolation structure 700. For example, a part of the isolation structure 700 may be formed on an inner wall of the first wafer trench 205-1 at a first deposition rate, while another part of the isolation structure 700 may be formed at an opening of the first wafer trench 205-1 at a second deposition rate greater than the first deposition rate. Since the second deposition rate is greater than the first deposition rate, when these two parts are deposited at the same time, the isolation material at the opening of the first wafer trench 205-1 may rapidly block the opening; and because the first deposition rate is slow, a part of the space in the first wafer trench 205-1 after blocking the opening is not filled with the isolation material, thereby forming the air gap 701. Since the air gap 701 has a low dielectric constant which is close to that of vacuum, the presence of the air gap 701 can reduce the overall dielectric constant of the isolation structure 700, which in turn reduces the parasitic capacitance, thereby reducing the electrical interference between two adjacent semiconductor bodies 200. In the process of forming the air gap 701, the size and position of the air gap 701 can be adjusted by controlling the first deposition rate and the second deposition rate, and the larger the ratio between the second deposition rate and the first deposition rate is, the larger the air gap 701 formed in the isolation structure 700 is and the better the effect of reducing the parasitic capacitance is. For example, a ratio α between the second deposition rate and the first deposition rate may have a range of 1≤a≤3. As an example, the ratio α may have a range of 1.5≤α≤2. In addition, those skilled in the art should understand that, the structure, composition and production process of the isolation structure 700 with the air gap 701 may be changed to obtain the various results and advantages described in this specification, without departing from the technical solutions claimed in the present disclosure.

The above-mentioned drain 220 is formed from the front side of the wafer 201, while in some other implementations, the drain 220 may also be formed from the back side of the wafer 201. For example, as shown in FIG. 13, the transistor may be formed by following operations. A plurality of first trenches 204 spaced apart in a third direction and each extending along a second direction are formed in the wafer 201 from the first surface 202 of the wafer 201. A dielectric material is deposited in the first trenches 204 to form a first dielectric layer 240. A first wafer trench 205-1 and a second wafer trench 205-2 arranged alternately in the second direction and each extending along the third direction in the wafer 201 are formed from the first surface 202 of the wafer 201. The size of the first wafer trench 205-1 in the first direction and the size of the second wafer trench 205-2 in the first direction are smaller than the size of the first trench 204 in the first direction. Thus, the first trench 204, the first wafer trench 205-1, and the second wafer trench 205-2 together divide a portion of the wafer 201 in the first direction into a plurality of initial semiconductor bodies 200′. An isolation structure 700 is formed in the first wafer trench 205-1. An initial gate structure 600′ is formed in the second wafer trench 205-2. An end of the initial semiconductor body 200′ is doped from the first surface 202 of the wafer 201 to form the source 210. The wafer 201 is thinned from the second surface 203 of the wafer 201. The end of the initial semiconductor body 200′ away from the first surface 202 is doped to form the drain 220.

In addition to the division operations mentioned above, the initial gate structure 600′ may also be divided by following operations. After the initial gate structure 600′ is formed in the second wafer trench 205-2, a gate isolation layer 640 is formed in the gap surrounded by the initial gate structure 600′. The wafer 201 is thinned from the second surface 203 of the wafer 201 to expose the first dielectric layer 240. A part of the first dielectric layer 240 is removed to form a first sub-trench (not shown) that exposes the initial gate structure 600′ and extends along the second direction. Part of the initial gate structure 600′ is removed through the first sub-trench to form a second sub-trench (not shown) extending along the third direction. Thus, the remaining initial gate structure 600′ covers the sidewall of the first wafer trench 205-1 extending along the first direction and has a ring shape. A dielectric material is filled in the first sub-trench and the second sub-trench. A gate cut structure 650 is formed at both ends of the remaining initial gate structure 600′ along the third direction, and the gate cut structure 650 extends through the initial gate structure 600′ along the first direction to divide the remaining initial gate structure 600′ into two gate structures 600 opposite to each other in the second direction.

In addition, it should be noted that, the isolation structure 700 may not only improve the isolation effect through the air gap 701, but also improve the isolation effect by providing the isolation conductive layer 720, and subsequently, the coupling effect between two adjacent transistors may be improved by grounding or connecting the isolation conductive layer 720 to a negative voltage. As an example, the isolation structure 700 may comprise an isolation dielectric layer 710 and an isolation conductive layer 720, and the isolation structure 700 may be formed by following operations. An initial isolation structure 700′ is formed in the first wafer trench 205-1, and the initial isolation structure 700′ comprises an isolation dielectric layer 710, an isolation conductive layer 720, and a conductive sacrificial layer (not shown). For example, an isolation material is deposited on an inner wall of the first wafer trench 205-1, and the isolation material may comprise, but is not limited to, silicon oxide, silicon oxynitride, or silicon nitride. The remaining space of the first wafer trench 205-1 is filled with a conductive material to form a conductive sacrificial layer, and the material of the conductive sacrificial layer may comprise, but is not limited to, at least one of tungsten, titanium nitride, copper, and silver. At least part of the conductive sacrificial layer is removed to form a first isolation trench. An isolation material is deposited on the inner wall of the first isolation trench to cover the conductive sacrificial layer. The remaining space of the first isolation trench is filled with a conductive material to form the isolation conductive layer 720, and the material of the isolation conductive layer 720 may comprise, but is not limited to, at least one of tungsten, titanium nitride, copper, and silver. At least part of the isolation conductive layer 720 is removed to form a second isolation trench, and the second isolation trench is filled with the isolation material. Thus, all of the isolation materials in the first wafer trench 205-1 constitute the isolation dielectric layer 710, which surrounds the isolation conductive layer 720 and the conductive sacrificial layer. When part of the initial gate structure 600′ is removed through the first sub-trench, the conductive sacrificial layer may be removed simultaneously to form the isolation structure 700. In this process, a part of the isolation dielectric layer 710 between the conductive sacrificial layer and the isolation conductive layer 720 may serve as an etch stop layer.

### S210

In S210, a capacitor structure 300 and a connection structure 400 are formed. The capacitor structure 300 comprises a first electrode layer 310, one end of the connection structure 400 is in contact with the semiconductor body 200, and at least a part of the other end of the connection structure 400 is located in the first electrode layer 310. As an example, the connection structure 400 may be formed in the process of forming the first electrode layer 310. In other words, the first electrode layer 310 and the connection structure 400 may be formed in the same fabrication process. For example, the first electrode layer 310 and the connection structure 400 are formed by an atomic layer deposition (ALD) process.

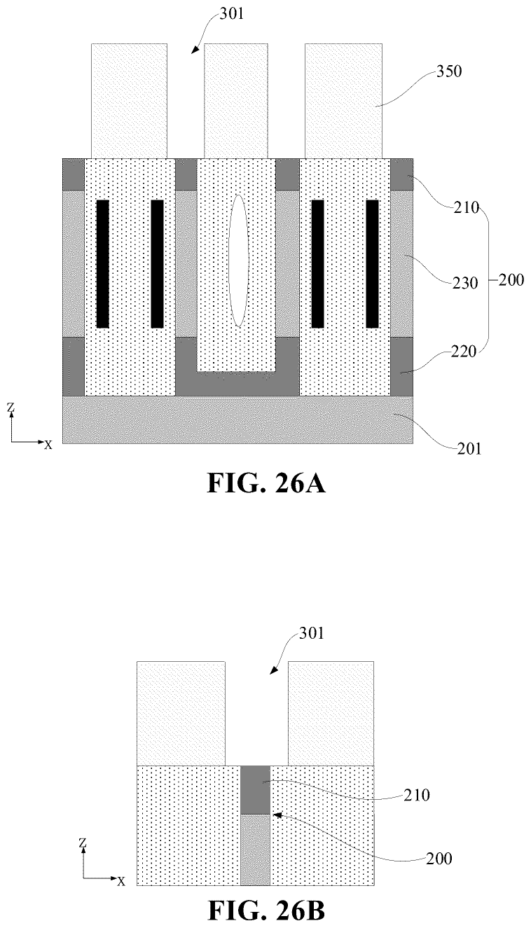

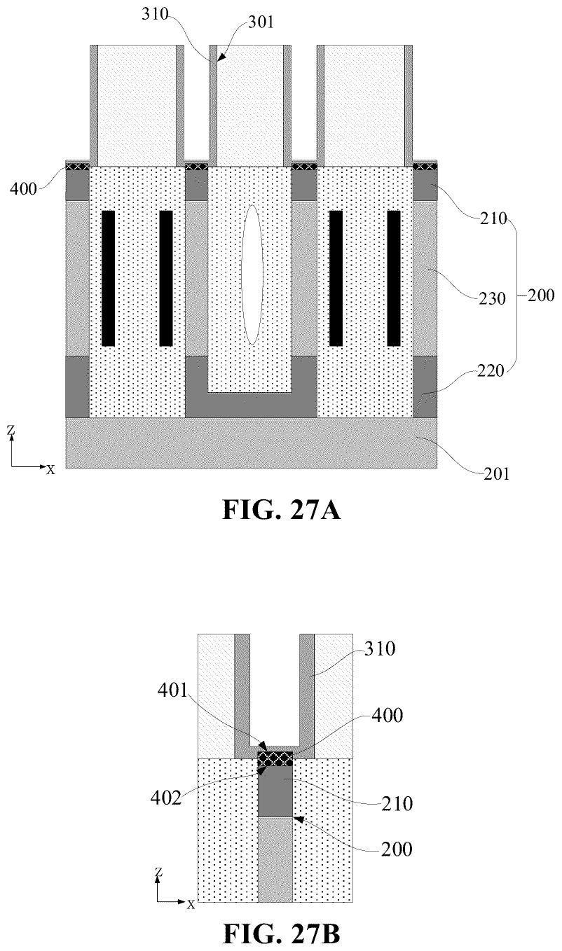

FIG. 25 illustrates a schematic cross-sectional view of an x-z plane of forming a filling dielectric layer 350 according to an implementation of the present disclosure; FIG. 26A illustrates a schematic cross-sectional view of an x-z plane of forming a capacitor hole 301 in the filling dielectric layer 350 according to an implementation of the present disclosure; FIG. 26B illustrates a partial enlarged schematic view of forming a capacitor hole 301 in the filling dielectric layer 350 according to an implementation of the present disclosure; FIG. 27A illustrates a schematic cross-sectional view of an x-z plane of forming a first electrode layer 310 and a connection structure 400 in the capacitor hole 301 according to an implementation of the present disclosure; and FIG. 27B illustrates a partial enlarged schematic view of forming a first electrode layer 310 and a connection structure 400 in the capacitor hole 301 according to an implementation of the present disclosure.

For example, the capacitor structure 300 and the connection structure 400 may be formed by following operations. As shown in FIG. 25, a filling dielectric layer 350 is formed on a side of the semiconductor body 200, wherein the filling dielectric layer 350 may be a single-layer structure or a multi-layer structure, which is not limited in the present disclosure. As shown in FIG. 26A and FIG. 26B, a capacitor hole 301 extending through the filling dielectric layer 350 in the first direction and exposing the semiconductor body 200 is formed. As shown in FIG. 27A and FIG. 27B, a metal material is deposited in the capacitor hole 301 by using an atomic layer deposition process, so that part of the metal material reacts with part of the semiconductor body 200 to form the connection structure 400, and at least part of remaining metal material forms the first electrode layer 310. Thereby the first electrode layer 310 and the connection structure 400 may be formed in situ.

Since the connection structure 400 is formed from the reaction between the metal material and the semiconductor body 200 during the formation of the first electrode layer 310, one end of the connection structure 400 formed by the above method is in contact with the semiconductor body 200, and at least a part of the other end of the connection structure 400 is located in the first electrode layer 310. It can be noted that, in the implementation of the present disclosure, by depositing the metal material in the capacitor hole 301 using an atomic layer deposition process, not only the deposition requirement of the capacitor hole 301 with a large aspect ratio can be met, but the connection structure 400 can also be formed simultaneously in the process of forming the first electrode layer 310, so that an ohmic contact between the semiconductor body 200 and the first electrode layer 310 can be achieved by means of the connection structure 400 while simplifying the process and reducing the cost.

As an example, the material of the connection structure 400 comprises molybdenum silicide. After the capacitor hole 301 is formed, the first electrode layer 310 and the connection structure 400 may be formed by using the atomic layer deposition process with a molybdenum-containing material as a precursor. The deposition temperature of the atomic layer deposition process may be, but is not limited to, less than 1000° C. For example, a molybdenum-containing precursor is introduced into a reaction chamber of the semiconductor equipment, so that the precursor is adsorbed on the inner wall of the capacitor hole 301, wherein the precursor may comprise, but is not limited to, molybdenum pentachloride. An inert gas is used to purge the reaction chamber to remove excessive unadsorbed precursor and possible byproducts. A reducing gas is introduced into the reaction chamber to chemically react with the precursor adsorbed on the inner wall of the capacitor hole 301 to form a molybdenum thin film. Then the reaction chamber is purged again with an inert gas to remove unreacted gases and byproducts. The above operations are repeated to deposit the molybdenum thin film layer by layer on the inner wall of the capacitor hole 301. In the above process, a part of the molybdenum thin film at the bottom of the capacitor hole 301 will react with the semiconductor body 200 to form a molybdenum silicide, that is, the connection structure 400, and the remaining unreacted part of the molybdenum thin film constitutes the first electrode layer 310.

It should be noted that the above-mentioned precursor may be, but is not limited to, molybdenum pentachloride. Other materials capable of chemically reacting with the reducing gas at a high temperature, such as less than 1000° C., and having high adsorptivity with the semiconductor body 200 may also be used as precursors for forming the connection structure 400 and the first electrode layer 310.

In addition, in the process of forming the first electrode layer 310 and the connection structure 400, the metal material may fill or almost fill the capacitor hole 301, so that the formed first electrode layer 310 has a pillar shape. In contrast, in the process of forming the first electrode layer 310 and the connection structure 400, the metal material may also cover only the inner wall of the capacitor hole 301, so that the formed first electrode layer 310 has a cylinder shape. In other words, the surrounding first electrode layer 310 can form an electrode hole.

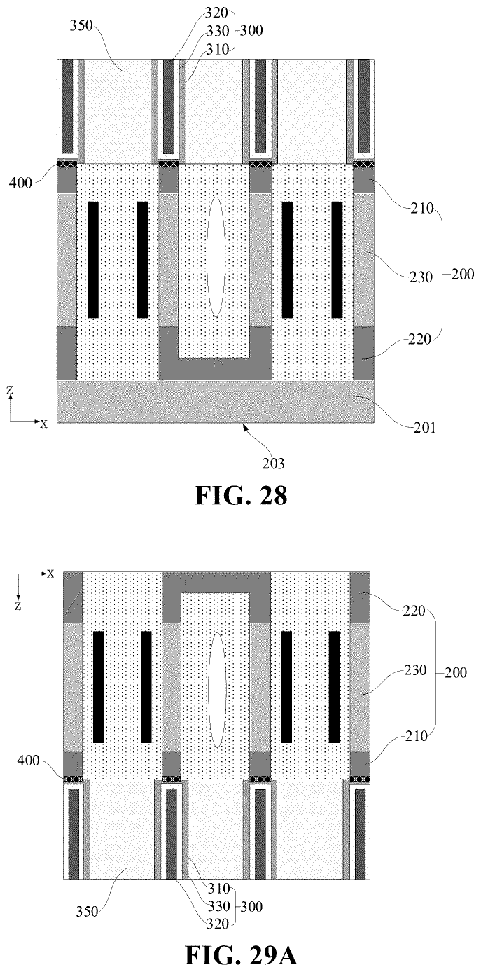

FIG. 28 is a schematic cross-sectional view of an x-z plane of forming a capacitor dielectric layer 330 and a second electrode layer 320 in an electrode hole according to an implementation of the present disclosure.

As shown in FIG. 28, taking the first electrode layer 310 with a cylinder shape as an example, the operation of forming the capacitor structure 300 may further comprise: forming a capacitor dielectric layer 330 on an inner wall of the electrode hole surrounded by the first electrode layer 310; and forming a second electrode layer 320 in the dielectric hole surrounded by the capacitor dielectric layer 330. Thus, the capacitor structure 300 comprises a first electrode layer 310, a second electrode layer 320 and a capacitor dielectric layer 330, the capacitor dielectric layer 330 is located between the first electrode layer 310 and the second electrode layer 320, and the first electrode layer 310 is located on the outer side of the second electrode layer 320.

In some other implementations, the first electrode layer 310 may also be located on the inner side of the second electrode layer 320. In this case, the filling dielectric layer 350 may comprise a second dielectric layer 351 and a filling sacrificial layer (not shown) stacked alternately in the first direction, wherein the material of the second dielectric layer 351 may comprise, but is not limited to, at least one of silicon nitride, silicon oxynitride, aluminum oxide, or the like, and the material of the second dielectric layer 351 may also be doped with a dopant such as boron or carbon. For example, the material of the second dielectric layer 351 may comprise silicon carbon nitride (SiCN) or silicon boron nitride (SiBN). The material of the filling sacrificial layer may comprise, but is not limited to, at least one of silicon oxide or silicon oxynitride. For example, the material of the filling sacrificial layer may comprise silicon oxide or silicon oxide treated with an organic solution, which may comprise, but is not limited to, Tetraethoxysilane (TEOS), Boron-Phosphosilicate Glass (BPSG), or Phosphosilicate Glass (PSG). If the first electrode layer 310 has a pillar shape, after the first electrode layer 310 and the connection structure 400 are formed, the filling sacrificial layer may be removed to expose at least part of a sidewall of the first electrode layer 310; the capacitor dielectric layer 330 is formed on the exposed sidewall of the first electrode layer 310; and the second electrode layer 320 is formed on a side of the capacitor dielectric layer 330 away from the first electrode layer 310. If the first electrode layer 310 has a cylinder shape, after the first electrode layer 310 and the connection structure 400 are formed, first, the supporting core 340 can be formed in the electrode hole surrounded by the first electrode layer 310, wherein the material of the supporting core 340 can be, but is not limited to, an elemental semiconductor material such as silicon (Si), a compound semiconductor material such as germanium silicon (GeSi), or polysilicon doped with a dopant such as boron. Then the filling sacrificial layer is removed to expose at least part of the sidewall of the first electrode layer 310; a capacitor dielectric layer 330 is formed on the exposed sidewall of the first electrode layer 310; and a second electrode layer 320 is formed on a side of the capacitor dielectric layer 330 away from the first electrode layer 310.

The above-mentioned materials of the first electrode layer 310 and the second electrode layer 320 may comprise, but are not limited to, at least one of metal, metal compound, semiconductor material, and silicide. For example, the materials of the first electrode layer 310 and the second electrode layer 320 comprise titanium nitride, titanium silicide or nickel silicide. The material of the capacitor dielectric layer 330 may comprise, but is not limited to, at least one of aluminum oxide, tantalum oxide, titanium oxide, yttrium oxide, zirconium oxide, zirconium silicon oxide, hafnium oxide, hafnium silicon oxide, hafnium silicon oxynitride, hafnium zirconate, lanthanum oxide, lanthanum aluminum oxide, lanthanum hafnium oxide, hafnium aluminum oxide, and prascodymium oxide.

In some implementations, the manufacturing method may further comprise: forming a bit line 800 extending along the second direction on a side of the semiconductor body 200 away from the capacitor structure 300. The material of the bit line 800 may be, but is not limited to, a metal material such as tungsten, copper or aluminum. In some other implementations, before forming the bit line 800, the bit line connection layer 810 may be further formed on a side of the semiconductor body 200 away from the capacitor structure 300, and the bit line connection layer 810 extends along the second direction. The material of the bit line connection layer 810 may comprise, but is not limited to, a semiconductor material comprising a P-type dopant such as boron or gallium or an N-type dopant such as phosphorus or arsenic.

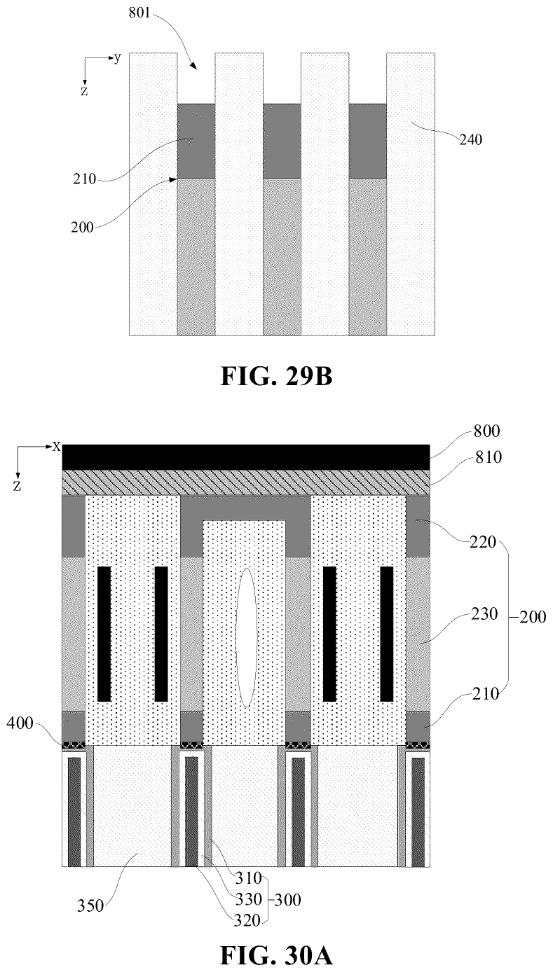

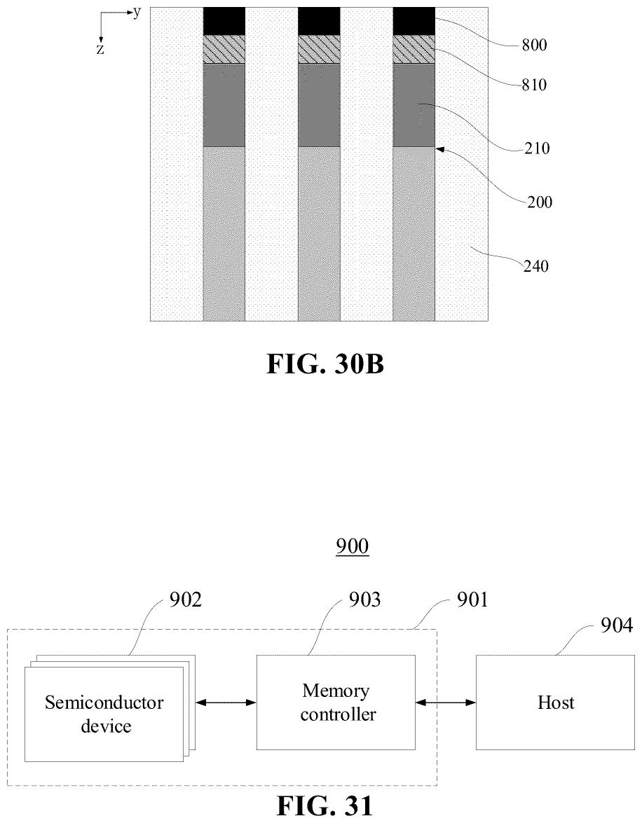

FIG. 29A illustrates a schematic cross-sectional view of an x-z plane of removing an undoped portion of the wafer 201 in an implementation of the present disclosure; FIG. 29B illustrates a schematic partial cross-sectional view of a y-z plane of removing an undoped portion of the wafer 201 in an implementation of the present disclosure; FIG. 30A illustrates a schematic cross-sectional view of an x-z plane of forming a bit line 800 in an implementation of the present disclosure; and FIG. 30B illustrates a schematic partial cross-sectional view of a y-z plane of forming a bit line 800 in an implementation of the present disclosure.

As shown in FIG. 28, a single-gate transistor is taken as an example. The wafer 201 may be thinned from the second surface 203 of the wafer 201 by a chemical mechanical polishing (CMP) process to expose the first dielectric layer 240. As shown in FIG. 29A and FIG. 29B, an undoped portion of the wafer 201 is removed from a side of the wafer 201 away from the first surface 202 to form a first bit line trench 801 extending along the second direction. As shown in FIG. 30A and FIG. 30B, a bit line connection layer 810 is formed in the first bit line trench 801; part of the bit line connection layer 810 is removed to form a second bit line trench (not shown) extending along the second direction; and a bit line 800 is formed in the second bit line trench.

In some implementations, the manufacturing method may further comprise: forming a second semiconductor structure 110, which may comprise, but is not limited to, at least one of a memory array or a peripheral circuit; and coupling the second semiconductor structure 110 with the first semiconductor structure 100, so that the second semiconductor structure 110 is located on a side of the first semiconductor structure 100 in the first direction and is connected to the first semiconductor structure 100.

In addition, an implementation of the present disclosure further provides a memory system comprising a controller and the above-mentioned semiconductor device. The controller is coupled to the semiconductor device, and is configured to control the semiconductor device to store data.

FIG. 31 illustrates a block diagram of a system with a semiconductor device according to an implementation of the present disclosure. The system 900 may be a mobile phone, a desktop computer, a laptop computer, a tablet computer, an vehicle computer, a game console, a printer, a positioning device, a wearable electronic device, a smart sensor, a virtual reality (VR) device, an augmented reality (AR) device, or any other suitable electronic device having storage therein. As shown in FIG. 31, the system 900 may comprise a host 904 and a memory system 901 having one or more semiconductor devices 902 and a memory controller 903. The host 904 may be a processor of an electronic device, such as a central processing unit (CPU), or may be a system-on-chip (SoC), such as an application processor (AP). The host 904 may be configured to send data to or receive data from the semiconductor device 902.

The semiconductor device 902 may be any of the semiconductor devices disclosed herein, such as the semiconductor device illustrated in FIGS. 12-16. According to some implementations, the memory controller 903 is coupled to the semiconductor device 902 and the host 904, and is configured to control the semiconductor device 902. The memory controller 903 may manage data stored in the semiconductor device 902 and communicate with the host 904.

In some implementations, the memory controller 903 is designed to operate in a low duty cycle environment, such as a secure digital (SD) card, a compact flash memory (CF) card, a universal serial bus (USB) flash drive, or other medium used in electronic devices such as personal computers, digital cameras, mobile phones, and the like. In some implementations, the memory controller 903 is designed to operate in a high duty cycle environment, such as an SSD or embedded multimedia card (eMMC), which is used as data storage for a mobile device such as smartphone, tablet, laptop, and the like, and an enterprise storage array. The memory controller 903 may be configured to control operations of the semiconductor device 902, such as read, erase, and program operations. The memory controller 903 may also be configured to manage various functions with respect to data stored or to be stored in the semiconductor device 902, which comprise, but not are limited to, bad-block management, garbage collection, logical-to-physical address conversion, wear leveling, and the like. In some implementations, the memory controller 903 is further configured to process error correction codes (ECC) with respect to data read from or written to the semiconductor device 902. Any other suitable function may also be performed by the memory controller 903 as well, such as formatting the semiconductor device 902. The memory controller 903 may communicate with an external device (e.g., host 904) according to a particular communication protocol. For example, the memory controller 903 may communicate with the external device through at least one of various interface protocols, such as a USB protocol, an MMC protocol, a Peripheral Component Interconnect (PCI) protocol, a PCI-express (PCI-E) protocol, an Advanced Technology Attachment (ATA) protocol, a Serial ATA protocol, a parallel ATA protocol, a Small Computer Small Interface (SCSI) protocol, an Enhanced Small Disk Interface (ESDI) protocol, an Integrated Drive Electronics (IDE) protocol, a Firewire protocol, etc.

It should be understood that the operations may be reordered, added, or deleted according to the various process flows shown above. As an example, the operations described in the present disclosure may be executed in parallel or in sequence or in different orders, as long as the desired results of the technical solutions in the present disclosure can be achieved, which is not limited herein.

The foregoing implementations do not constitute a limitation on the protection scope of the present disclosure. It should be understood by those skilled in the art that various modifications, combinations, sub-combinations, and substitutions may be made according to design requirements and other factors. Any modifications, equivalent substitutions and improvements made within the spirit and principle of the present disclosure should be encompassed within the protection scope of the present disclosure.

What is claimed is:

1. A semiconductor device, comprising:
a first semiconductor structure comprising:
a semiconductor body extending along a first direction;
a capacitor structure located on a side of the semiconductor body in the first direction and comprising a first electrode layer; and
a connection structure, wherein a first end of the connection structure in the first direction is in contact with the semiconductor body, and at least a part of a second end of the connection structure is located in the first electrode layer.

2. The semiconductor device of claim 1, wherein the connection structure protrudes from a surface of the first electrode layer facing toward the semiconductor body in the first direction and is in contact with the semiconductor body.

3. The semiconductor device of claim 1, wherein the connection structure comprises a first connection surface and a second connection surface opposite to each other in the first direction, and a surface of the first electrode layer facing toward the semiconductor body is located between the first connection surface and the second connection surface in the first direction.

4. The semiconductor device of claim 1, wherein a material of the connection structure and a material of the first electrode layer comprise a same metal element.

5. The semiconductor device of claim 4, wherein the metal element comprises molybdenum.

6. The semiconductor device of claim 4, wherein the material of the connection structure comprises a metal silicide having the metal element.

7. The semiconductor device of claim 1, wherein the connection structure is a single-layer structure.

8. The semiconductor device of claim 1, wherein a size of the connection structure in the first direction is less than 10 nm.

9. The semiconductor device of claim 1, wherein a size of an end of the first electrode layer facing toward the semiconductor body in a second direction is greater than a size of the connection structure in the second direction, and the second direction intersects the first direction.

10. The semiconductor device of claim 1, wherein a size of an end of the semiconductor body in contact with the connection structure in a second direction is same as a size of the connection structure in the second direction, and the second direction intersects the first direction.

11. A manufacturing method of a semiconductor device, comprising:
forming a semiconductor body extending along a first direction; and
forming a capacitor structure and a connection structure,
wherein the capacitor structure is located on a side of the semiconductor body in the first direction and comprises a first electrode layer, one end of the connection structure in the first direction is in contact with the semiconductor body, and at least a part of the other end of the connection structure is located in the first electrode layer.

12. The manufacturing method of claim 11, wherein the connection structure is formed in a process of forming the first electrode layer.

13. The manufacturing method of claim 11, wherein the first electrode layer and the connection structure are formed in a same fabrication process.

14. The manufacturing method of claim 11, wherein the first electrode layer and the connection structure are formed by an atomic layer deposition process.

15. The manufacturing method of claim 11, wherein forming the capacitor structure and the connection structure comprises:
forming a filling dielectric layer on a side of the semiconductor body;
forming a capacitor hole extending through the filling dielectric layer along the first direction; and
depositing a metal material in the capacitor hole by using an atomic layer deposition process to form the first electrode layer and the connection structure in situ.

16. The manufacturing method of claim 15, wherein depositing the metal material in the capacitor hole by using the atomic layer deposition process to form the first electrode layer and the connection structure in situ comprises:
depositing the metal material in the capacitor hole, so that part of the metal material reacts with part of the semiconductor body to form the connection structure, and at least part of remaining metal material forms the first electrode layer.

17. The manufacturing method of claim 15, wherein depositing the metal material in the capacitor hole to form the first electrode layer and the connection structure in situ comprises:
forming the first electrode layer and the connection structure by using the atomic layer deposition process with a molybdenum-containing material as a precursor.

18. The manufacturing method of claim 17, wherein the precursor comprises molybdenum pentachloride.

19. The manufacturing method of claim 15, wherein a deposition temperature of the atomic layer deposition process is less than 1000° C.

20. A memory system, comprising:
a controller; and
a semiconductor device comprising:
a first semiconductor structure comprising:
a semiconductor body extending along a first direction;
a capacitor structure located on a side of the semiconductor body in the first direction and comprising a first electrode layer; and
a connection structure, wherein a first end of the connection structure in the first direction is in contact with the semiconductor body, and at least a part of a second end of the connection structure is located in the first electrode layer,
wherein the controller is coupled to the semiconductor device and configured to control one or more operations of the semiconductor device.
